(19) United States
(12) Patent Application Publication
(10) Pub. No.: US 2025/0109493 A1
(43) Pub. Date: Apr. 3, 2025

(54) CHEMICAL VAPOR DEPOSITION SYSTEM WITH HOT-WALL HYBRID FLOW REACTOR AND REMOVABLE REACTOR FLOOR

(71) Applicant: VEECO INSTRUMENTS INC., Plainview, NY (US)

(72) Inventors: Johannes Kaeppeler, Lontzen (BE); Ajit Paranjpe, Basking Ridge, NJ (US)

(73) Assignee: VEECO INSTRUMENTS INC., Plainview, NY (US)

(21) Appl. No.: 18/899,637

(22) Filed: Sep. 27, 2024

Related U.S. Application Data
(60) Provisional application No. 63/586,195, filed on Sep. 28, 2023.

(51) Int. Cl. C23C 16/44; C23C 16/458

(52) U.S. Cl. CPC C23C 16/4401; C23C 16/4583

(57) ABSTRACT

A chemical vapor deposition system includes a reaction chamber and a removable wafer carrier including a wafer carrier body that is configured to support a wafer. The system includes a removable cover plate that supports the wafer carrier body and a susceptor base is disposed below the cover plate that supports the cover plate. The removable cover plate is in a nested arrangement with respect to the susceptor base as a result of first nesting structure of the removable cover plate mating with a second nesting structure of the susceptor base.

### CROSS-REFERENCE TO RELATED PATENT APPLICATIONS

This application is based on and claims priority to U.S. provisional patent application 63/586,195, filed Sep. 28, 2023, the entire contents of which is incorporated by reference herein as if expressly set forth in its respective entirety herein.

### TECHNICAL FIELD

The present technology is generally related to semiconductor fabrication technology and, more particularly to chemical vapor deposition processing and associated systems and more particularly, to chemical vapor deposition system that includes a removable reactor floor that is configured to be easily removed by an automated handling system to permit for cleaning and optimized preventative maintenance of the system.

### BACKGROUND

Certain processes for fabrication of semiconductors can require a complex process for growing epitaxial layers to create multilayer semiconductor structures for use in fabrication of high-performance devices, such as light emitting diodes (LEDs), laser diodes, optical detectors, power electronics, and field effect transistors. In this process, the epitaxial layers are grown through a general process called chemical vapor deposition (CVD). One type of CVD process is called metal organic chemical vapor deposition (MOCVD). In MOCVD, reactant gases are introduced into a reaction chamber within a controlled environment that enables the reactor gas to react on a substrate (commonly referred to as a “wafer”) to grow thin epitaxial layers.

During epitaxial layer growth, several process parameters are controlled, such as temperature, pressure, and gas flow rate, to achieve desired quality in the epitaxial layers. Different layers are grown using different materials and process parameters. For example, devices formed from compound semiconductors such as III-V or IV-IV semiconductors, typically are formed by growing a series of distinct layers. In this process, the wafers are exposed to a combination of reactant gases, typically including a metal organic compound such as an alkyl source that includes a group III metal, such as aluminum (Al), gallium (Ga), indium (In), and combinations thereof, and a hydride source that includes a Group V element, such as nitrogen (N), phosphorus (P), arsenic (As), or antimony (Sb), typically in the form of NH₃, AsH₃, PH₃, or an Sb metalorganic, such as tetramethyl antimony. In the case of IV-IV at least two elements of Silicon (Si) and Carbon (C) and Germanium (Ge) are formed by typically used as hydrides for example SiH₄, Si₂H₆ C₂H₄, C₃H₈, GeH₄ or chlorine containing gases, such as SiH₂Cl₂ and SiHCl₃. Chlorine containing gases (e.g., Cl₂, HCl and CHₓCl₄₋ₓ where x=0 to 3 may also be added. Generally, the alkyl and hydride sources are combined with a carrier gas, such as nitrogen (N₂), Argon (Ar) and hydrogen (H₂), or a mixture of a combination of H₂ with N₂ or Ar which do not participate appreciably in the reaction. In these processes, the alkyl and hydride sources flow over the surface of the wafer and react with one another to form a III-V compound of the general formula In_{X}Ga_{Y}Al_{Z}N_{A}As_{B}P_{C}Sb_{D}, where X+Y+Z equals approximately one, A+B+C+D equals approximately one, and each of X, Y, Z, A, B, C, and D can be between zero and one. In other processes, commonly referred to as “halide” or “chloride” processes, the Group III metal source is a volatile halide of the metal or metals, most commonly a chloride such as GaCl₂. In yet other processes, bismuth is used in place of some or all the other Group III metals.

A suitable substrate for the reaction can be in the form of a wafer having metallic, semiconducting, and/or insulating properties. In some processes, the wafer can be formed of sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

In a rotating disc reactor architecture-based CVD process chamber, one or more wafers are positioned within, commonly referred to as a “wafer carrier,” so that the top surface of each wafer in a rotating carousel is exposed, thereby providing a uniform exposure of the top surface of the wafer to the gaseous ambient within the reaction chamber for the deposition of semiconductor materials. The wafer carriers are typically machined out of a highly thermally conductive material such as graphite and are often coated with a protective layer of a material such as silicon carbide or tantalum carbide. Each wafer carrier has a set of circular indentations, or pockets, on its top surface in which individual wafers are placed. The wafer carrier is commonly rotated at a rotation speed on the order from about 10 to 1500 RPM or higher. While the wafer carrier is rotated, the reactant gases are introduced into the chamber from a gas distribution device, positioned upstream of the wafer carrier. The flowing gases pass downstream toward the wafer carrier and wafers, desirably in a laminar flow.

During the CVD process, the wafer carrier is maintained at a desired elevated temperature by heating elements, often positioned beneath the wafer carrier. Therefore, heat is transferred from the heating elements to the bottom surface of the wafer carrier and flows upwardly through the wafer carrier to the one or more wafers. Depending on the process, the temperature of the wafer carrier is maintained on the order of between about 550-1200° C. for GaN based films. Higher temperatures (e.g., up to about 1450° C.) are used for growth of AlN based films and lower temperatures (e.g., down to about 350° C.) are used for growth of AsP films. For some materials such as SiC, temperatures of 1600° C.-1700° C. are required. Other temperature ranges are suitable for other materials such as SiC, Si and SiGe or 2D materials such as graphene, and sulphides or selenides of tungsten and molybdenum. The reactive gases, however, are introduced into the chamber by the gas distribution device at a much lower temperature, typically about 200° C., or lower, to inhibit premature reaction of the gases.

As the reactant gases approach the rotating wafer carrier, the temperature of the mixture of reactant gases substantially increases and viscous drag of the rotating wafer carrier impels the gases into rotation about an axis of the wafer carrier so that the gases flow around the axis and outwardly toward a perimeter of the wafer carrier across the boundary region near the surface of the wafer carrier. Depending on the reactant gases used in the process, pyrolysis can occur in or near the boundary region at an intermediate temperature between that of the gas distribution device and the wafer carrier. This pyrolysis creates intermediate species that facilitate growth of a crystalline structure. The gases that are not consumed continue to flow toward the perimeter and over the outer edge of the carrier, where they are removed from the process chamber through one or more exhaust ports disposed below the wafer carrier.

Traditional CVD SiC reactors use a hot-wall or warm-wall design to achieve the very high wafer temperatures (approximately 1650° C.) and to crack the process gases for the silicon (e.g., silane and chlorosilane) and carbon sources (alkanes) to generate the intermediate reactive species for growth of SiC on the wafer. In such reactors, the deposition rate on sections of the hot walls of the reactor and particularly, the surfaces around or over the wafer can be comparable or higher than the growth rate on the wafer.

A typical single-wafer-wafer hot wall CVD SiC reactor consists of a preheat region that connects the gas injector to the hot-wall reactor cell, a reactor cell, and a downstream exhaust. The walls of the reactor cell are maintained at approximately 1650° C., while the temperature in the preheat and exhaust sections varies from approximately 1650° C. where they connect to the reactor cell to approximately 50° C. where they connect to the water-cooled walls. The injector is typically divided into multiple lateral zones (e.g., 3 zones) so that the flow rate and gas composition can be set within each of the zones to achieve good uniformity of thickness and doping. The growth rate and doping profile vary both along the flow direction and perpendicular to the flow direction. The growth rate decreases in the direction of the gas flow. The flow rates are set to achieve a linear (or near linear) decrease in growth rate from the leading edge of the wafer to the trailing edge of the wafer. This converts to a uniform growth rate on the wafer as the wafer rotates on its axis. The wafer is placed on a rotating carrier to obtain on-axis wafer rotation.

Relatively thick SiC films (10 μm-15 μm) are required for most applications up to 1200V, and even thicker films (up to 100 mm) are required for devices rated above 1200 V. The SiC films deposited on the reactor surfaces become a source of particles once the cumulative thickness exceeds 350 μm-750 μm. For a 15 μm film and 500 μm of cumulative growth, this represents ˜30 runs or 30 hours of operation assuming a typical cycle time of 1 hr. for a single wafer reactor.

For the chlorosilane chemistry, SiC is deposited on surfaces that are above −1450° C., while other materials such as carbon and silicon are deposited on surfaces that are between 1100° C. and 1450° C. Silicon and carbon films are more prone to shedding particles since the films are low density with a rough morphology and are weakly adhered to the surfaces.

For the chlorosilane chemistry, the deposition rate for all materials drops significantly below 1100° C. with very little deposition below 1000° C. For a typical hot-wall CVD SiC reactor, the parasitic deposition on the various surfaces limits the preventative maintenance (PM) interval to 350 μm-750 μm.

While the buildup of parasitic coatings in the reactor is a source of particles, the effect on doping level in the SiC is even more pronounced. Very tight wafer-to-wafer variation in doping level of <5% is required to meet the functional requirements for the SiC devices. Parasitic coatings make it difficult to maintain a predictable doping level in the film. Random and uncorrectable drifts in doping level contribute to device yield loss.

To maintain process repeatability and acceptable defectivity, a PM during which the parts that have been excessively coated are cleaned or replaced must be performed frequently (every alternate day). The short PM interval diminishes reactor availability, lowers factory throughput, increases consumable costs, and increases labor costs. Customers desire a PM interval of 1500 μm-3000 μm for the upcoming ramp in wafer volume. Improvements to the conventional CVD SiC reactor to extend the PM interval to 3000 μm resulting in improved yield and productivity for 8″ wafers while meeting or exceeding the other performance metrics is the subject of this disclosure.

In conventional reactor designs, the floor of the reactor is not removable and preventative maintenance requires for the system to be shut down to allow for cleaning of the reactor floor as well as other surfaces within the reactor. This results in costly and disruptive downtime.

### SUMMARY OF THE DISCLOSURE

In one embodiment, a chemical vapor deposition system includes a reaction chamber and a removable wafer carrier that includes a wafer carrier body that is configured to support a wafer. Unlike traditional reactor design, the present system includes a removable cover plate that supports the wafer carrier body. A susceptor base is disposed below the cover plate that supports the cover plate. The removability of the cover plate by an automated handling system permits cleaning and optimized preventative maintenance of the system and significantly reduces costly downtime.

The system includes a pair of first end effector tracks formed within and along a top surface of the susceptor base for receiving a pair of fork arms of an end effector for lifting the cover plate away from the susceptor base to allow removal and maintenance of the removable cover plate. The system further includes a pair of second end effector tracks formed within and along a top surface of the cover plate for receiving the pair of fork arms of the end effector for lifting the wafer carrier to allow removal thereof.

In another embodiment, a chemical vapor deposition system includes a reaction chamber and a removable wafer carrier including a wafer carrier body that is configured to support a wafer. The system includes a removable cover plate that supports the wafer carrier body and a susceptor base is disposed below the cover plate that supports the cover plate. The removable cover plate nests with the susceptor base as a result of a male structure of the removable cover plate being received within a female structure of the susceptor base.

In another embodiment, a multi-wafer chemical vapor deposition system includes a reaction chamber and a removable segmented multi-wafer carrier comprising a plurality of wafer carrier segments. Each wafer carrier segment includes: (1) a wafer carrier disc supported within the wafer carrier segment; (2) a wafer carrier body segment for supporting a wafer; and (3) a susceptor base segment disposed below the cover plate segment that supports the cover plate segment. There is a pair of first end effector tracks formed within and along a top surface of the susceptor base segment for receiving a pair of fork arms of an end effector for lifting the cover plate segment away from the susceptor base segment to allow removal and maintenance of the removable cover plate segment. In addition, there is a pair of second end effector tracks formed within and along a top surface of the cover plate segment for receiving the pair of fork arms of the end effector for lifting the wafer carrier body to allow removal thereof.

In yet another embodiment, a method is provided for performing preventative maintenance of a chemical vapor deposition system that includes a reaction chamber. The method includes the steps of:
inserting an end effector into a pair of second end effector tracks defined along a top surface of a removable cover plate;
lifting a removable wafer carrier by raising the end effector, the wafer carrier including a wafer carrier body that is configured to support a wafer;
inserting the end effector into a pair of first end effector tracks defined along a top surface of a susceptor base, the first end effector tracks being closed off by an underside of the cover plate;
lifting the removable cover plate by raising the end effector; and
removing the removable cover plate from the reaction chamber and replacing the removable cover plate with a clean cover plate using the end effector.

The summary above is not intended to describe each illustrated embodiment or every implementation of the present disclosure. The figures and the detailed description that follow more particularly exemplify these embodiments.

### BRIEF DESCRIPTION OF THE DRAWINGS

The disclosure can be more completely understood in consideration of the following detailed description of various embodiments of the disclosure, in connection with the accompanying drawings, in which:

FIG. 1 is a cross-sectional view of a chemical vapor deposition system.

FIG. 2 is a top view of an exemplary chemical vapor deposition system.

FIG. 3 is an exploded view of a single wafer chemical vapor deposition system with a removable reactor floor.

FIG. 4A is a plan view of a segmented cover plate.

FIGS. 4B and 4C are partial plan views of a two-piece susceptor with gas foil rotation features.

FIG. 5 is an exploded view of a segmented susceptor that is part of a multi-wafer chemical vapor deposition system.

FIG. 6A is a cross-sectional view of an automated wafer loading and unloading mechanism in accordance with one embodiment.

FIG. 6B is a cross-sectional view of the automated wafer loading and unloading mechanism in a first position in which the mechanism is in position for raising a wafer and wafer carrier (ring).

FIG. 6C is a cross-sectional view of an automated wafer loading and unloading mechanism in a second position in which the wafer and wafer carrier (ring) are in a raised position.

FIG. 6D is a cross-sectional view of the automated wafer loading and unloading mechanism in a third position in which the mechanism is in position for raising the reactor floor (cover plate and disc).

FIG. 6E is a cross-sectional view of an automated wafer loading and unloading mechanism in which the reactor floor is in a raised position.

FIG. 7A is an enlarged close-up view of a portion of an automated wafer loading and unloading mechanism during an operating position.

FIG. 7B is an enlarged close-up view of the portion of the automated wafer loading and unloading mechanism during a transfer position.

FIG. 8 is an enlarged close-up showing the nested arrangement between a removable cover plate and a susceptor base.

FIG. 9 is an exploded view of another single wafer chemical vapor deposition system with a removable reactor floor.

FIG. 10A is a cross-sectional view of the automated wafer loading and unloading mechanism in a position for raising the reactor floor (cover plate, base cover plate, and disc).

FIG. 10B is a cross-sectional view of an automated wafer loading and unloading mechanism in which the reactor floor of FIG. 10A is in a raised position.

While embodiments of the disclosure are amenable to various modifications and alternative forms, specifics thereof shown by way of example in the drawings will be described in detail. It should be understood, however, that the intention is not to limit the disclosure to the particular embodiments described. On the contrary, the intention is to cover all modifications, equivalents, and alternatives falling within the spirit and scope of the subject matter as defined by the claims.

### DETAILED DESCRIPTION

As wafer sizes for III-V epitaxial growth have increased from 150 mm diameter wafers to larger diameter wafers, such as 200 mm and 300 mm diameter wafers, consumer preference has generally tended towards single wafer reactors, such as the PROPEL™ GaN MOCVD system, due to its superior uniformity and process control. An example embodiment of the PROPEL™ GaN MOCVD system is disclosed in US Pat. App. Publ. No. 2017/0067163, the contents of which are incorporated by reference herein. Advantages for single wafer reactors include rotational averaging for improved deposition uniformity without leading and/or trailing edge effects, low centripetal forces on the wafer, and a wide process window

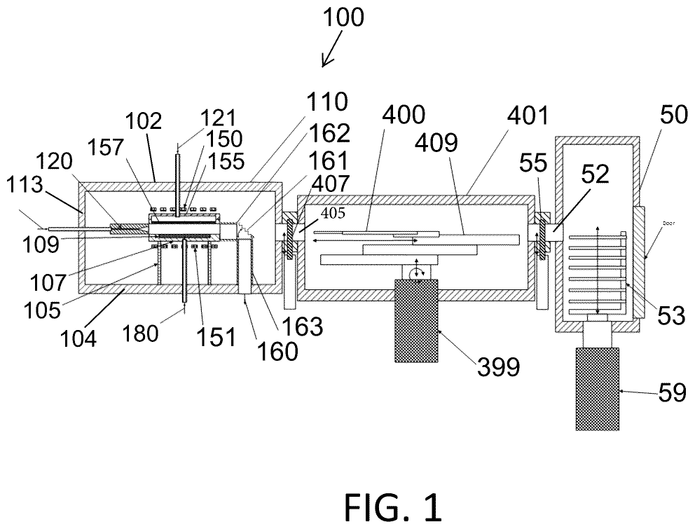

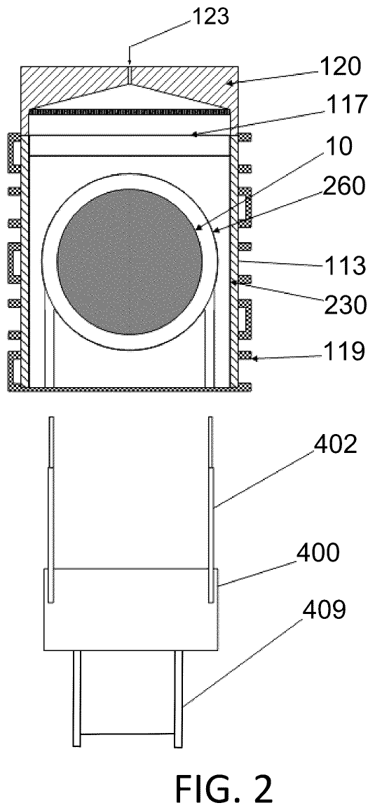

Referring to FIGS. 1-3, a chemical vapor deposition system 100 in the form of a single wafer, hot-wall, hybrid flow reactor for CVD SiC is depicted in accordance with an embodiment of the disclosure. The chemical vapor deposition system 100 includes a reaction chamber 110 (occasionally referred to herein as a “process chamber” or “reactor” or “reactor chamber”), configured to define a process environment space, in which an injector (gas injector) 120 (which alternatively can be referred to as a “gas distribution device”) can be arranged within the environment space. FIGS. 1-2 are simplified in order to more easily show certain basic features of the system, including internal components within the reaction chamber 110.

As described herein and as is known, the system 100 includes one or more susceptors that hold and heat semiconductor wafers 10 (also referred to as a “wafer substrate”). As is known, a rotating susceptor holds a single wafer and rotates it while the gases used in reaction chamber 110 flow over the wafer 10. It is called a susceptor because, in addition to holding the wafer 10, it is made of a suitable material, such as graphite, and can be inductively heated by an RF coil located outside the reactor cell or by resistance heated filaments outside the reactor cell, thereby controllably heating the wafer 10 to the desired deposition temperature.

The present disclosure describes and illustrates both a single wafer design (single susceptor) as well as a planetary (multi-wafer) wafer design. The reaction chamber 110 can have a conventional design and generally includes a top wall 102, an opposite bottom wall 104, along with a sidewall 113.

### Gas Injector

The system 100 can include any number of different types of gas injectors and can include one or more gas injectors. For example, FIGS. 1-3 illustrate one exemplary gas injector 120 that is a sidewall gas injector in that gas injected laterally from one sidewall into the reaction chamber 110. It will be appreciated that, as is known, a sidewall gas injector injects one or more gases into the reaction chamber 110 in a direction inward from the sidewall. As shown in FIGS. 1-3, the gas injector 120 can be located at one end of the reaction chamber 110 and can include a plurality of discharge openings or nozzles through which the one or more gases are injected into the interior of the reaction chamber 110. The discharge openings can be formed in a uniform or non-uniform manner and can be arranged in groups or zones.

It will also be appreciated that different process gases can be supplied to the various gas inlets of the gas injector 120. The gas injector 120 can be a water-cooled injector with the water cooling being achieved by water inlets and outlets that are formed in the gas injector block in which the gas inlets are formed. In FIG. 2, the reference character 123 indicated a feed inlet for the process gas(es) into the gas injector 120.

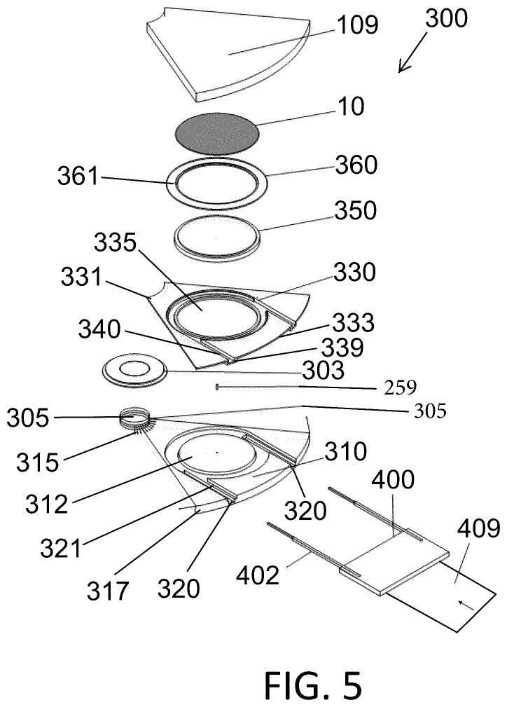

The gas injector 120 is thus connected to a gas delivery system for supplying process gases to be used in the chemical vapor deposition process, such as a carrier gas and one or more reactant gases such as a metal organic compound and a group V or a group IV source of reactants. Thereafter, the gas injector 120 can be configured to direct a flow of combined process gases into the process environment. In another embodiment shown in FIG. 5, the gas injector 120 can be a centrally located multi-zone injector 305 for the distribution of reactant gases into the reaction chamber in a crossflow direction. The injector 120 can also be connected to a coolant system configured to circulate a liquid through the injector 120, to maintain the temperature of the process gas at a desired temperature during operation.

In one embodiment, H₂/HCl is injected through the gas injector 120 to minimize the deposition on the leading edge of the reactor ceiling and the reactor floor to an acceptable level. These portions of the reactor 110 cannot be removed by the automated handling system and are replaced only during a preventative maintenance that is performed after 1500 μm-3000 μm of cumulative deposition. Since a safe buildup amount is 300 μm over 3000 μm of deposition, the acceptable deposition rate on these surfaces should be <10% of the growth rate on the wafer or <5 μm/hr. for a growth rate of 50 μm/hr. on the wafer.

FIGS. 1-3 thus show one location for the gas injector 120 which is along one side or end of the reactor 110 to affect a substantially horizontal or crossflow of reactant gases over substrates positioned within the reaction chamber 110.

Following introduction of the process gases into the reaction chamber 110, the process gas flows across a wafer carrier (which supports the wafer substrate (“wafer”) 10), and over the top surface of the wafer carrier, including an individual wafer supporting disc 250, where an individual wafer substrate 10 is held. Often the process gas in proximity to the top surface of the wafer carrier is predominantly composed of a carrier gas, such as H₂ and/or N₂, and/or Ar, with some amount of first or second reactive gas components. The first reactive gas component can be an alkyl source Group III metal, and the second reactive gas component can be a hydride source Group V element. For SiC deposition, the first reactive gas is typically a chlorosilane or a Silane with Hydrochloride while the second reactive gas is typically an alkane.

The flow of process gas continues to flow around a periphery of the wafer carrier and is eventually exhausted from the reaction chamber 110 through the exhaust system, via one or more ports located within the process environment space.

The system 100 can be thought of as including an upper (ceiling or lid) region and a lower (substrate) region. The upper region includes the ceiling of the reaction chamber 110, while the lower region contains the wafer carrier.

Along the sidewall 113 of the system, there is also a load port for loading and unloading the wafer carrier. The loading and unloading of the wafer carrier are discussed in more detail below.

### Heated Sidewall

The reaction chamber 110 comprises a hot wall reactor and the sidewall 113 comprises a heated sidewall 113. Deposition can also build up on the sidewalls of the reactor and the use of heated sidewalls serves to reduce the degree of deposition. For example, injection of HCl/H₂ through the ceiling (as described herein) along with active heating of the sidewalls to approximately 1800° C. keeps the deposition rate on the sidewalls to less than 10% of the growth rate on the wafer. Heating of the sidewalls also improves the temperature uniformity of the wafer along a direction that is perpendicular to the flow direction. Temperature uniformity along the flow direction is adjustable using multi-zone heating.

FIG. 2 shows a sidewall heater 119 for heating the sidewall 113.

In one embodiment, the heated sidewalls 113 are maintained at temperatures to ˜1800° C. keeps the deposition rate on the sidewalls 113 to <10% of the growth rate on the wafer 10. Heating of the sidewalls 113 also improves the temperature uniformity of the wafer 10 along a direction that is perpendicular to the flow direction. Temperature uniformity along the flow direction is adjustable using multi-zone heating.

The wafer temperature uniformity is controlled by the variation in the reactor cell temperature both along the flow direction and perpendicular to the flow direction. In the flow direction, multiple zones of heating (e.g., 3) can be used to create a temperature profile on the reactor cell that is high or low at the center of the wafer relative to the edge of the wafer. This controllability is required to compensate for heat losses from the wafer edge and to optimize the doping profile so that the shape of the doping profile matches the shape of the growth profile across the wafer. When the profiles are matched, the device characteristics are uniform across the wafer.

In a direction that is perpendicular to the flow direction, the wafer temperature is higher in the center relative to its edge. This is due to heat loss from the sidewalls of the reactor that cool the reactor sidewalls relative to the actively heated ceiling and floor of the reactor cell. The sidewalls are indirectly heated by the heaters for the ceiling and the floor. By adding heaters along the sidewall, the wafer temperature uniformity in the direction perpendicular to the flow is significantly improved. The sidewall heaters 119 (FIG. 2) can be separate or extensions of the floor and ceiling heaters 150 that are placed adjacent to the sidewalls 113.

Thus, the system described herein includes multiple independently controlled heaters surrounding the reactor cell to control the temperature and temperature distribution on various heater surfaces which yields the benefits described herein.

### Heated and Purged Ceiling

In the system 100, the ceiling of the reaction chamber defined by the ceiling top plate 155 and ceiling showerhead plate 157) is heated and can include a showerhead architecture for injecting purge gases into the reaction chamber 110. More particularly, as described herein, carrier and/or etching gases can be injected through showerhead holes formed in the ceiling into the reaction chamber 110. In FIG. 1, a ceiling showerhead plate 157 is illustrated through which the showerhead holes are formed.

At the top of the reaction chamber 110 there can be a lid that is defined by a top wall with water-cooling for temperature control. The top wall also includes through ports that pass completely through the top wall and other openings for receiving related equipment as described herein. The top wall can thus include an internal chamber (annular space) in which water is circulated. The top wall includes an inner surface or face. The lid can thus be water-cooled.

A ceiling heater assembly 150 is provided and can be positioned between the top wall and the hollow interior of the reaction chamber 110 that contains the wafer carrier 260 and is disposed along the inner face of the top wall. The ceiling heater assembly 150 can include one or more support brackets that are coupled to the inner face. The illustrated ceiling heater assembly 150 can be a resistance 3-zone heater; however, it can equally have another type of construction. FIG. 1 generally shows the ceiling heater assembly 150 with a ceiling top plate 155 disposed below the ceiling heater assembly 150.

The ceiling heater assembly 150 is intended to heat the ceiling of the system 100. More particularly, in the exemplary embodiment discussed herein, the ceiling heater assembly 150 operates at higher temperatures than the temperatures of the heater (discussed herein) that heats the susceptor.

The ceiling of the system 100 can be formed of a top ceiling plate (plate 155) and a lower ceiling plate, in the form of the ceiling showerhead plate 157, that is spaced from the top ceiling plate. There is an open space formed between the top ceiling plate 155 and the ceiling showerhead plate 157. This open space can be thought of as being a gas manifold that distributes gas and permits gas to being injected into the reaction chamber 110. The open space is a rectangular cavity or an annular cavity depending on the type (and shape) of reactor.

The top ceiling plate 155 is configured and intended to absorb energy from the RF heater (which can be in the form of an RF ceiling heater coil) or a resistance heater which operates at a higher temperature as the ceiling plate.

The ceiling showerhead plate 157 includes a plurality of showerhead holes that communicate directly into the reaction chamber 110. Gases that are injected into the open space flow throughout the open space and exit through the showerhead holes. The showerhead holes can be formed in different patterns to allow the uniform distribution of the gases into the reaction chamber 110.

As described herein, the showerhead design permits ceiling purging and more particularly, the showerhead in the ceiling permits injection of carrier gas (H₂, N₂, Ar or a combination thereof) and for some applications, injection of an etching gas (e.g., HCl, Cl₂, TBCl, etc.).

The ceiling of the system 100 is mounted to the lid using suitable mounting structures. For example, an outer support ring and an outer intermediate ring can be used to mount the ceiling heater assembly to the lid. The outer intermediate ring is located radially inward from the outer support ring. These rings can be formed of quartz.

The ceiling of the system 100 is actively heated with a heat source separate from a susceptor heating system. In accordance with one aspect of the present system 100, the operating temperature of the ceiling heater assembly 150 is different than bottom (susceptor) heater assembly that heats the wafer carrier. Therefore, the temperature gradient between the ceiling and the susceptor holding the substrate can be reduced to suppress the convection by temperature gradient towards the ceiling.

For example, the operating temperature of the ceiling heater assembly 150 is higher than the operating temperature of the bottom (susceptor) heater assembly. For example, the operating temperature of the ceiling heater assembly 150 can be between 600° C. and 1200° C., 700° C. and 1100° C., 1600° C. and 1800° C., while the operating temperature of the bottom heater assembly is between 600° C. to 900° C., 700° C. and 1400° C., 1500° C. and 1700° C. The ceiling heater can also be set so that the temperature of the ceiling is lower than the susceptor which might be beneficial for the growth of certain materials within a stack.

The gas purging results from the introduction of gases into the reaction chamber 110 through the ceiling (showerhead holes in the ceiling showerhead plate 157). In one embodiment, one or more showerhead gas modules can be provided along the lid and pass through the ports formed through the top wall and passes through a port formed in the top ceiling plate. In this way, one or more gases, such as a carrier gas, such as H₂/Ar, and/or an etching gas, such as HCl, are directly injected into the open space and then exit through the showerhead holes into the reaction chamber 110 according to a desired, predefined pattern.

The gas injector 120 (e.g., a lateral gas injector as shown in FIGS. 1 and 2) in conjunction with reduced deposition on the walls of the reactor cell results in good uniformity. The growth rate reduces near-linearly from the leading edge of the wafer to the trailing edge of the wafer. The growth rate is relatively uniform in a direction perpendicular to the flow. In FIG. 1, the gas feed (e.g., purge gas) to the gas injector 120 is shown at 121.

The combination of an actively heated and purged ceiling, HCl/H₂ injection through the gas injector 120, and maintaining the sidewalls in the range of (approximately) 1800° C. results in a significantly lower growth rate on reactor surfaces. The growth rate is near zero over most of the reactor surfaces and deposition is confined to a short region along the sidewall 113 of the reactor. This can be further reduced through optimization of the reactor cell geometry and the distribution of gas flows through the injector and the ceiling. Reduction of deposition on various surfaces also reduces the likelihood of cracking of coated surfaces due to the stress induced by thick deposited films further increasing the lifetime of the parts.

The peak growth rate on the floor of the reactor can be ˜2× higher than the average growth rate on the wafer. Accordingly, portions of the floor that get excessively coated such as the carrier, wafer, wafer support ring, and satellite disc must be removed by the automated handling system. In accordance with the present disclosure, the systems described herein address and overcome this problem by providing a reactor floor that is removable for easy cleaning thereof.

It will be appreciated that the ceiling construction described above, and the operating parameters discussed above are only exemplary and not limiting of the scope of the present disclosure.

### SiC Application

In the case of SiC epitaxy, the ceiling temperature of the systems disclosed herein is heated between 1600° C. and 1800° C. due to heating by for example an RF pancake coil (RF ceiling heater coil). The temperature of the contact to the quartz should not exceed 1200° C. Therefore, at least two intermediate rings can be in between the ceiling and the quartz support to lower the temperature and additionally reduce the thermal stress. The material selection for the ceiling and the susceptor is more restrictive in SiC applications because of the high temperature and the interaction with the carrier and process gases. In the case of SiC epitaxy, there will be only graphite with TaC coating or SiC coating or solid SiC. The limit of SiC coating is removal of the coating via sublimination if it comes into proximity with a colder surface.

### GaN Application

For a GaN application, the ceiling temperature is heated between 700° C. and 1100° C. (or lower temperatures) due to heating by the RF pancake coil (RF ceiling heater coil). The material selection for the ceiling and the susceptor is less restrictive but nevertheless it should be protected from hot ammonia which requires a protective coating of the graphite. The preferred coating is SiC, but TaC or pyrolytic boron nitride can alternatively be used as a coating. Also, solid SiC can be used for some parts such as cover plates, satellites, satellite rings, etc.

The susceptor can also be heated to 700° C. and 1400° C. by resistive heating using filaments that are preferably made of W or Re. Resistive heating provides multiple zone temperature control which is not possible with RF heating.

### GaAs/InP Application

For GaAs/InP application, the temperature of the ceiling can be between 600° C. and 1200° C. (or lower temperatures) using RF with the pancake coil (RF ceiling heater coil). The material selection for the ceiling and the susceptor is less restrictive and preferably is highly purified graphite.

### GaAs/InP Application

Resistive heating up to 600° C. to 1100° C. using filaments that are preferably made of pure graphite can be used.

It will be appreciated that the above values are only exemplary in nature of certain application and not limiting of the scope of the present disclosure.

### Susceptor Heating Assembly

A susceptor heating assembly 151 is provided for heating the wafer carrier and is located beneath the wafer carrier.

The susceptor heating assembly 151 typically has a different construction than the ceiling heater assembly 150. More particularly, for the planetary cross-flow architecture, the susceptor heating assembly can have an outer susceptor heater coil and an inner susceptor heater coil that is coupled to the outer susceptor heater coil. The outer susceptor heater coil is located radially outward from the inner susceptor heater coil. The outer susceptor heater coil can include a water inlet for delivering water into the coil and a water outlet for withdrawing water from the coil. Similarly, the inner susceptor heater coil includes a water inlet for delivering water into the coil and a water outlet for withdrawing water from the coil. Alternatively, it can have a different construction than the aforementioned one.

Gas Injection into the Reaction Chamber

As mentioned herein, gases can be injected into the reaction chamber 110 in at least two different locations and by at least two different means (i.e., two different injector types).

First, the ceiling showerhead plate 157 permits injection of one or more carrier gases and/or one or more etching gases. The showerhead design allows for these gases to be injected through the heated ceiling into the reaction chamber 110 in a controlled manner. Second, the lateral gas injector 120 acts to inject the reactant gases such that the reactant gases flow within the reaction chamber 110 over a single wafer substrate 10 or wafer substrates 10 on the satellites.

### Parasitic Deposition on the Ceiling

As mentioned, one of the primary disadvantages of conventional planetary reactor systems is the parasitic deposition on the ceiling. Parasitic deposition can cause particle generation and alter the thermal balance within the reactor which leads to process drift. To avoid this, in-situ chamber etching is often used but this will increase the total cycle time for a production run. In-situ cleaning typically reduces component lifetimes and therefore increases the costs of consumables. In-situ etching is impractical for certain materials, such as SiC, that are difficult to etch in typical in-situ cleaning gases, such as Cl₂, HCl and NF₃.

Additionally, the parasitic deposition consumes precursor materials which will not end up in the active layer on the substrate. This reduces the total precursor usage efficiency and limits the process window for good uniformity (e.g., for thickness, composition and doping) on the wafer.

The system 100 disclosed herein is configured to avoid or significantly minimize the parasitic deposition on the ceiling. This can eliminate or reduce the need for in-situ cleaning, enhance component lifetimes, increase growth rates, increase gas usage efficiency, and broaden the process window for deposition uniformity on the wafer. Elimination or reduction of in-situ cleaning shortens the cycle time and extends the preventative maintenance cycle.

The exemplary system 100 uses a combination of flows introduced by vertical (showerhead design) and horizontal (lateral gas injector 120) gas inlets.

### Exhaust

The system 100 of FIG. 1 includes a peripheral exhaust port 160 for exhausting gases from the exhaust chamber 110. In combination with the controlled sidewall temperature, the peripheral exhaust port 160 is configured to limit parasitic deposition and avoid exhaust clogging. It will be appreciated that any number of different peripheral exhausts can be used in the system 100. As shown in FIG. 1, the exhaust system can include an exhaust liner 162 and an exhaust tube 163 that leads to the exhaust port 160 that is operatively connected to a vacuum system or some other exhaust means. There can also be a shutter 161 that opens the path for unloading and loading the removable parts. The shutter 161 thus gives access to the end effector 400 while loading and unloading.

### Gear Box

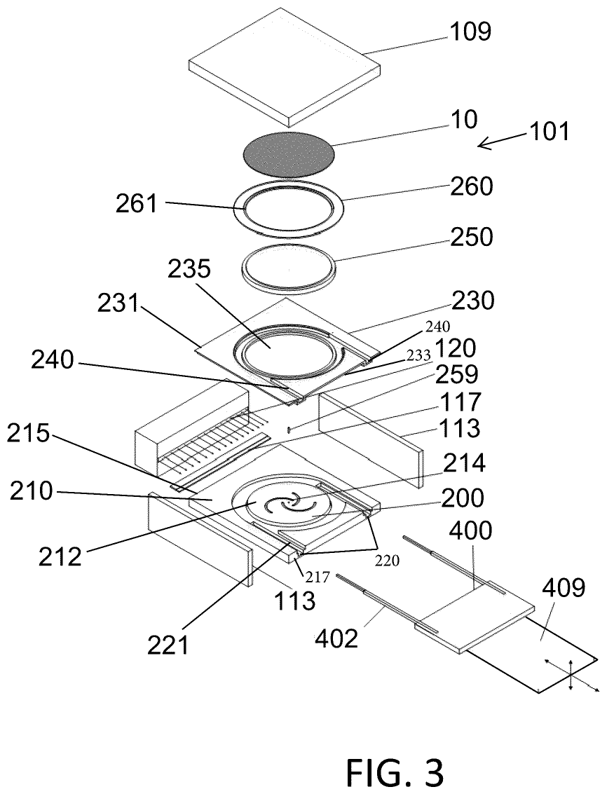

A conventional gear box can be used in the single wafer design of FIG. 3.

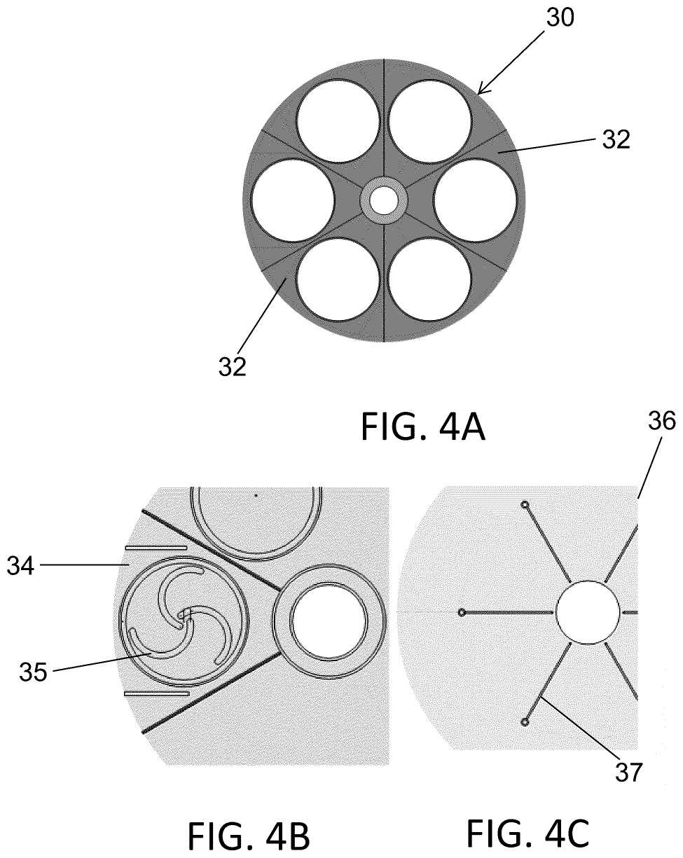

As mentioned with respect to the drive mechanism of the multi-wafer systems of FIGS. 4A-C and 5, the wafer carrier and the satellites are driven in such a way that each can be independently controlled and rotated at least in one embodiment. In particular, the wafer carrier (wafer carrier body) is configured to rotate relative to the base at a first rate and the individual satellites mounted within the substrate carrier can rotate relative to the base at a second rate different than the first rate. In one embodiment, the wafer carrier rotates between about 50 RPM and 400 RPM, while the satellites rotate between 20 RPM and 40 RPM; however, this is merely one example. The planetary configuration of the mechanical drive can use a single motor to drive both the satellites and the wafer carrier though reduction gears can be used as described herein. In one embodiment, the wafer carrier and the satellites rotate in the same direction. It will be appreciated that in other applications, the speeds of the wafer carrier and satellites can be different from the aforementioned ranges.

Gear boxes can be operatively coupled to a pair of satellites for rotating them at a desired speed. The gear boxes can sit on the bottom plate of the system 100. These same gear boxes can function to rotate the wafer carrier as well.

### Gas Driven Rotation Drive

U.S. Pat. Nos. 6,878,395 and 6,983,620, each of which is hereby expressly incorporated by reference in its entirety, describe and illustrate a gas drive with single satellite gas control that can be modified and implemented in the systems described herein. Gases are fed into the vacuum tight reaction chamber by a multiple gas feed through a hollow shaft ferrofluidic. Each gas channel can be controlled by an MFC (mass flow controller) and supplied to a single satellite. The gas is supplied to a hollow pin to the individual gas drive for each satellite.

Modeling confirms growth rate and uniformity are achievable on 200 mm wafers for a variety of materials. Growth of SiC, GaN, InGaN, GaAs, InAlP, and InGaAsP were evaluated. Deposition on ceiling can be eliminated (SiC) or reduced by >100× (for III-N and As/P) compared to conventional crossflow reactors. Gas usage efficiency and growth rates are comparable or higher than crossflow planetary. Carrier rotational speeds is about 5-20 RPM are adequate for many applications. If higher speeds (e.g., 50-400 rpm) are desired, the gearbox drive mechanism may have to be used.

FIG. 1 generally illustrates one exemplary gas drive mechanism incorporated into the system 100. More specifically, a hollow shaft 180 is shown to feed a gas into the vacuum tight reaction chamber 110. For example, the feed gas can be in the form of Ar or H₂ or a mixture of Ar and H₂. When the system comprises a multi satellite arrangement, the gases are fed into the vacuum tight reaction chamber by a multiple gas feed. For example, if there are eight satellites, there can be eight separate satellite gas feeds (which can be controlled by the MFC). Each gas channel can be controlled by the MFC and supplied to a single satellite. The gas can be supplied to a hollow pin to the individual gas drive for each satellite. In this embodiment, the system thus utilizes a gas driven rotation drive mechanism to control the rotation of each satellite and the wafer carrier.

In gas driven drive mechanism (gas foil rotation), the gas flows through gas distribution channels with a flow direction that is directed circumferentially, so that it not only raises the substrate holder from a bearing surface, but also imposes a rotary momentum on the substrate holder, so that the holder is driven in rotation. Accordingly, in gas driven drive mechanism, the susceptor is formed to include gas distribution channels that are arranged in spiral from a center point of the relevant susceptor section and as a result, the fed-in gas flow is set into a rotational motion which drives the substrate holder into rotation.

FIG. 3 shows a gas driven drive mechanism for a single wafer reactor design.

FIGS. 4A-C shows one exemplary gas driven drive mechanism (gas foil rotation) structure for a multi-wafer reactor design. In particular, FIGS. 4A-C illustrate a separated (segmented) carrier that is formed of a cover plate 30. In a segmented carrier design, the cover plate 30 (FIG. 4A) is segmented into a plurality of discrete segments or sections 32 (“pie shaped sections”) with each section 32 having an opening to accommodate one satellite/satellite ring (a substrate holder). FIGS. 4B and 4C illustrate a two-piece susceptor with FIG. 4C illustrating a bottom susceptor part 34 that includes a plurality of gas distribution channels 35. In the illustrated embodiment, the plurality of gas distribution channels 35 are arranged in a spiral manner. FIG. 4B illustrates a top susceptor part 34 that can be thoughts of as including a plurality of surface sections (zones) each of which is aligned with one opening formed in the cover plate 30 and thus, each surface section has an associated satellite/satellite ring. Within each surface section (zone), there are spiral gas distribution channels 35 that are arranged such that the fed-in gas flow is set into a rotational motion which drives the substrate holder into rotation. The area(s) in which the spiral gas distribution channels 35 represents a bearing surface. FIG. 4C shows a bottom susceptor part 36 with gas distribution channels 37 (arranged in a spoke-like pattern).

While FIGS. 4A-C illustrate a cover plate 30 that is segmented, it will be appreciated that the above-described gas driven drive mechanism (gas foil rotation) can be equally implemented in a non-segmented cover plate design, as well as the other systems described herein, such as system 100. In other words, gas foil rotation can be incorporated into both single wafer systems as well as multi-wafer planetary systems.

FIG. 3 is an exploded view of chemical vapor deposition system 101 that is similar to the system 100 and can therefore include the same components and have the same features described herein with respect to system 100. As a result, like components are numbered alike. Of note, in FIG. 3, the heater assemblies, as well as all of the features and details of the gas injectors, are eliminated. In FIG. 3, the gas injector 120 is shown as well as the heated sidewalls 113. A front cover plate 117 can also be provided and is located proximate the gas injector 120 and extends between the sidewalls 113. The front cover plate 117 thus defines a section of the reactor floor and as described herein, the front cover plate 117 can remain fixed in place and is not removable during normal operation of the system. The system 101 also includes a ceiling 109.

### Susceptor for Single Wafer System

FIG. 3 shows one exemplary susceptor 200 and in particular, the susceptor 200 comprises a single wafer design. The susceptor 200 includes a susceptor base (reactor base) 210 that is disposed between the sidewalls 113. The susceptor base 210 has a first (top) surface and a second (bottom) surface. The susceptor base 210 can include a raised center susceptor region 212 that is equipped for gas driven drive mechanism (gas foil rotation). The raised center susceptor region 212 includes a plurality of gas distribution channels 214. The gas distribution channels 214 are arranged in a swirl (spiral) pattern. As previously mentioned, gas flows through gas distribution channel 214 with a flow direction that is directed circumferentially, so that it not only raises the substrate holder from a bearing surface, but also imposes a rotary momentum on the substrate holder, so that the holder is driven in rotation.

In the illustrated embodiment, the raised center susceptor region 212 has a circular shape.

In accordance with the present disclosure, the susceptor base 210 includes a set of recessed first tracks 220 that take the form of a pair of recessed channels that are parallel to one another. The set of first tracks 220 are linear tracks that are formed on either side of the raised center susceptor region 212. As illustrated, the set of first tracks 220 do not extend along the entire length of the raised center susceptor region 212 but instead only partially extend. In one embodiment, the set of first tracks 220 extend at least half of the length of the raised center susceptor region 212. Each first track 220 can have a stepped construction in that a ledge 221 can be formed on either side and at the top of the rectilinear shaped recessed channel.

The susceptor base 210 has a first end 215 at which the gas injector 120 is located and has an opposite second end 217. Each of the first tracks 220 is open along the second end 217 (but does not extend to the first end 215).

The susceptor 200 also includes a cover plate 230 and in accordance with the present disclosure, the cover plate 230 is removable which provides a number of advantages as discussed herein. The cover plate 230 has a first (top) surface and a second (bottom) surface. The second surface of the cover plate 230 is designed to complement and engage the first surface of the susceptor base 210 in that, in use, the cover plate 230 is disposed over and supported by the susceptor base 210. As shown, the cover plate 230 can have a slightly smaller footprint than the underlying susceptor base 210. The cover plate 230 has an opening 235 formed therein. The shape and size of the opening 235 is complementary to the shape and size of the raised center susceptor region 212 since the raised center susceptor region 212 axially aligns with and is exposed within the opening 235.

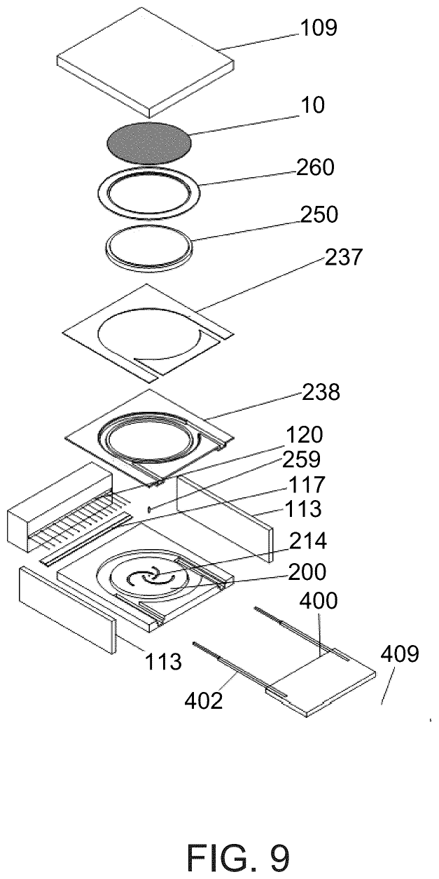

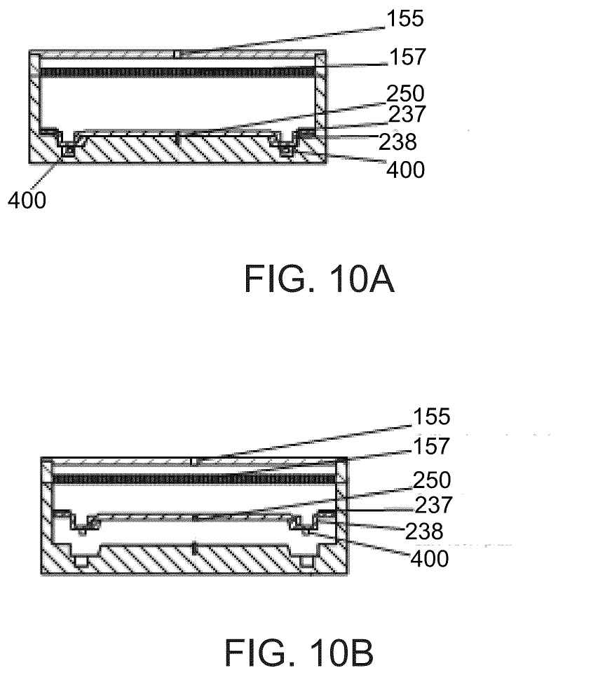

It will also be appreciated that in another embodiment, shown in FIGS. 9, 10A and 10B, the cover plate can be divided into two parts, namely, a thin top cover plate 237 and a base cover plate 238. In other words, the thin top cover plate 237 has a smaller thickness and is disposed over the base cover plate 238 to define a two layer cover plate structure. This arrangement provides a simpler cleaning as the thin top cover plate 237 can be made of solid SiC and the base cover plate 238 can be made of TaC coated graphite. The thinner and flat SiC cover plates 237 of the system can be easily grinded down by the parasitic SiC coating. The TaC coated graphite base cover plate 238 need little or even no cleaning.

In accordance with the present disclosure, the cover plate 230 includes a set of recessed second tracks 240 that take the form of a pair of recessed channels that are parallel to one another. The set of second tracks 240 are linear tracks that are formed on either side of the opening 235. As illustrated, the set of second tracks 240 do not extend along the entire length of the opening 235 but instead only partially extend. In one embodiment, the set of second tracks 240 extend at least half of the length of the opening 235. The second tracks 240 are thus open along the first surface of the cover plate 230.

The cover plate has a first end 231 that faces the gas injector 120 and an opposite second end 233. The first end 231 can be located adjacent to the front cover plate 117 which is a separate structure relative to the cover 230. The second tracks 240 are open along the second end 217 but not the first end 231 since they do not extend all the way to the first end 231.

The recessed nature of the second tracks 240 along the first surface creates a pair of protruding rails 239 along the second surface of the cover plate 230. As illustrated, the recessed second tracks 240 can have a rectilinear shape and therefore, the protruding rails 239 have a rectilinear shape (i.e., the protruding rails 239 have inverse shape as the recessed second tracks 240). The bottom protruding rails 239 are configured to be received within the first tracks 210 and more particularly, the protruding rails 239 seat on the ledges 221 associated with the first tracks 220. Upstanding sidewalls that are along the sides ledges 221 serve to guide and hold the protruding rails 239 in place. In this manner, the cover plate 230 is coupled to the susceptor base 210. Accordingly, it will be appreciated that the removable cover plate is in a nested arrangement with respect to the susceptor base as a result of first nesting structure (e.g., rails 239) of the removable cover plate mating with a second nesting structure (ledges 221) of the susceptor base. It is possible for the male/female nature of these structures to be reversed in that is it possible for the susceptor base to have male features and the underside of the cover plate to have female features.

It will be appreciated that since the protruding rails 239 sit on ledges 221, they do not enter into the rectilinear shaped recessed channel of the first tracks 220 and thus do not create interference within the recessed channels of the first tracks 220. The cover plate 230 thus closes off and covers the open first tracks 220. The second tracks 240 remain open along the top surface of the cover plate 230.

Thus, the cover plate 230 and the susceptor base 210 fit and are arranged in a nested arrangement.

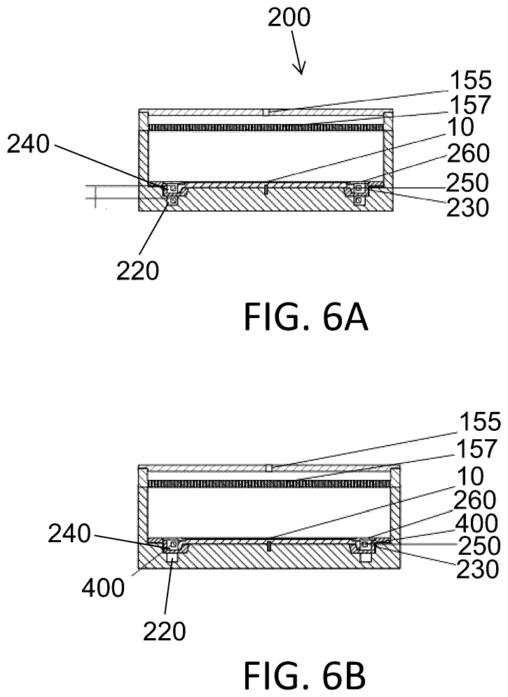

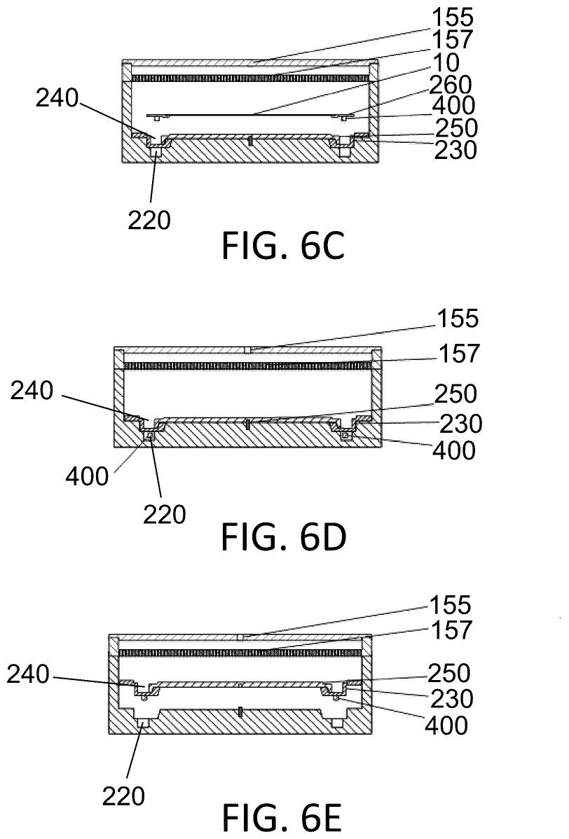

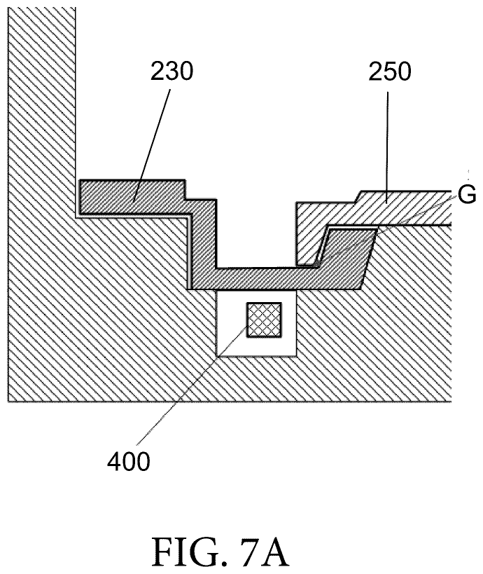

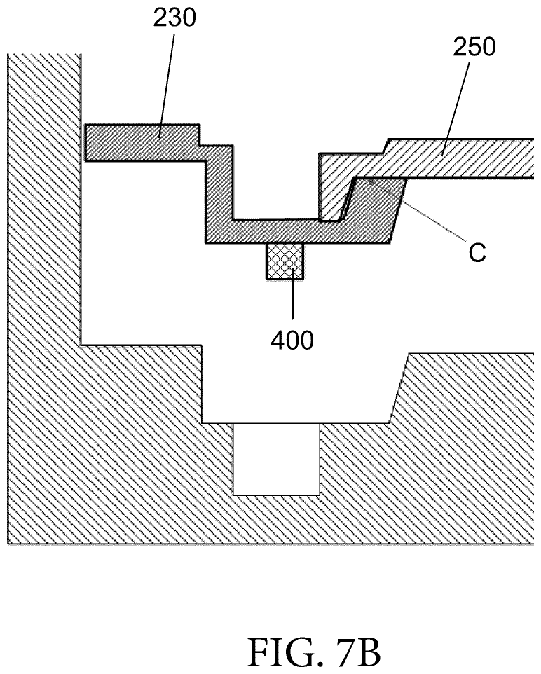

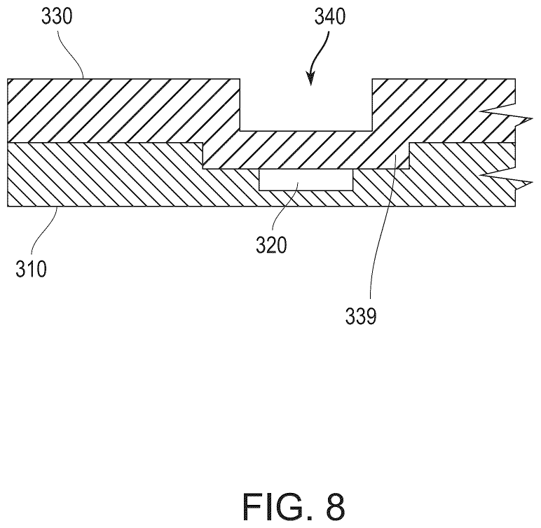

The susceptor 200 also includes a disc 250 that is supported by the cover plate 230 and extends across the opening 235 and is thus in fluid communication with the gas distribution channels 214 formed in the raised center susceptor region 212 to allow for the driving of the disc 250. As understood, the disc 250 is driven and provides a support surface on which the wafer 10 rests. An axle 259 can be provided and is received within a hole formed in the underside of the disc 250 (See, FIG. 6B) to define an axis of rotation of the disc 250. As shown in FIG. 7A, during operation, there is a gap (G) between the disc 250 and the cover plate 230. This gap means that there is no contact between the disc 250 and the cover plate 230 to let the disc 250 freely rotate during the operation. In contrast, as shown in FIG. 7B, during the transfer position, which is described in detail herein, there is no gap and the disc 250 and the cover plate 230 and instead, the disc 250 lays directly on and in contact with the topside of the cover plate 230 during the transfer of the cover plate 230 out of the reactor. This contact is identified in FIG. 7B as (C).

A carrier ring (wafer carrier or wafer carrier body) 260 surrounds the disc 250 and rests on it. Rotation of the disc 250 is imparted into rotation of the wafer 10. The carrier ring 260 thus has an annular shape with an inner ledge on which the wafer 10 rests.

The carrier ring 260 can at least partially cover the inner ends of the second tracks 240 in that outer edges of the carrier ring 260 extend across inner ends of the second tracks 240. The carrier ring 260 has an upper face, a lower face, and inner and outer sidewalls. The inner sidewall includes a wafer shoulder 261 constructed and arranged to receive the wafer 10 thereon.

The two different sets of recessed tracks permit for independent removal of: (1) the wafer carrier (carrier ring 260 and wafer 10) and (2) removal of the cover plate 230. More specifically, the second tracks 240 permit for insertion of a tool (described below) that is disposed below and directly underneath outer portions of the carrier ring 260 that support the wafer 10. To remove the wafer, the carrier ring 260 is lifted by a wafer carrier transporter using a (robotic) tool that is inserted into second tracks 240 and then moved upward to cause a lifting of the carrier ring 260 and the wafer 10 off of the cover plate 230.

In contrast to conventional reactor design, the cover plate 230 itself is removable from the reaction chamber 110 to allow for improved and more efficient preventative maintenance of the system 101. In other words, by permitting the cover plate 230 to be lifted and removed and a replacement cover plate 230 to be inserted, there is very little downtime associated with maintenance. In conventional design, the cover plate 230 is not removable and the system 101 needs to be shut down (no wafer processing) for a period of time to allows for adequate cleaning (preventative maintenance) of the internal components, including the cover plate 230.

To remove the cover plate 230, the cover plate 230 is lifted by a transporter using a (robotic) tool that is inserted into first tracks 220 and then moved upward to cause a lifting of the cover plate 230. It will be appreciated that the cover plate 230 is intended to be lifted and removed after the carrier ring 260 and the wafer 10 have been removed.

### Susceptor for Planetary Wafer System

FIG. 5 shows one exemplary susceptor segment 310 and in particular, the susceptor segment 310 is part of a planetary wafer design that is made up of a plurality of susceptor segments 310 that define the complete susceptor. The planetary wafer design is similar to the single wafer design shown in FIG. 5 in that the susceptor segment 310 configuration permits removal of the cover plate for maintenance, replacement, etc.

FIG. 5 thus depicts a separated (segmented) carrier construction that can be used in the systems described herein. As illustrated, in this embodiment, the carrier is formed of a plurality of discrete susceptor segments 310 or sections (“pie shaped sections”) with FIG. 5 illustrating one susceptor segment 310. Each susceptor segment 310 generally has the same construction as the carrier (susceptor) in the single wafer design (FIG. 3) and more particularly, each susceptor segment 310 includes a (segmented) susceptor base (reactor base) 310 that is disposed between the sidewalls 113. The susceptor base 310 has a first (top) surface and a second (bottom) surface. The susceptor base 310 can include a raised center susceptor region 312.

In one embodiment, shown in FIG. 5, the susceptor base 310 can be rotatable about axle 259 using traditional drive techniques. For example, similar to that shown in FIGS. 4A-4C, the susceptor base can be equipped for a gas driven drive mechanism (gas foil rotation). In that embodiment, the raised center susceptor region 312 includes a plurality of gas distribution channels (similar to FIGS. 4A-4C). The gas distribution channels are arranged in a swirl (spiral) pattern. As previously mentioned, gas flows through gas distribution channel with a flow direction that is directed circumferentially, so that it not only raises the substrate holder from a bearing surface, but also imposes a rotary momentum on the substrate holder, so that the holder is driven in rotation. However, as shown in FIG. 5, the susceptor segment 310 does not have to be equipped for gas foil rotation and instead can be driven (rotated) by other conventional drive means.

In the illustrated embodiment, the raised center susceptor region 312 has a circular shape.

In accordance with the present disclosure, the susceptor base 310 includes a set of recessed first tracks 320 that take the form of a pair of recessed channels that are parallel to one another. The set of first tracks 320 are linear tracks that are formed on either side of the raised center susceptor region 312. As illustrated, the set of first tracks 320 do not extend along the entire length of the raised center susceptor region 312 but instead only partially extend. In one embodiment, the set of first tracks 320 extend at least half of the length of the raised center susceptor region 312. Each first track 320 can have a stepped construction in that a ledge 321 can be formed on either side and at the top of the rectilinear shaped recessed channel.

The susceptor base 310 has a first (inner end 315) at which a center gas injector 305 is located and has an opposite second end 317. Each of the first tracks 320 is open along the second end 317 (but does not extend to the first end 315). The center gas injector 305 can be a center cross-flow injector that is centrally positioned within the reaction chamber 110 to affect a substantially horizontal or crossflow of reactant gases over each substrate (wafer) positioned within the reaction chamber 110. For example, with reference to FIG. 5, a multi-zone injector 305 can be positioned adjacent to the top surface of the wafer carrier, so as to have a lateral component with respect to the one or more substrate wafers 10 positioned within the wafer carrier. As such, the center gas injector 305 can provide a variable horizontal flow of reactant gas towards exposed growth surfaces of the one or more substrate wafers 10. As described herein, the multi-zone center gas injector 305 can be raised and lowered between a load and unloading position, which is the lowered position, in which the wafer carrier can be loaded and unloaded through the load port and a process position, which is the raised position, in which reactant gas flows horizontally out of the center gas injector 305 in a radially outward direction over the wafers that are located on the satellites. With the segmented carrier design, the center injector 305 can remain stationary.

A front cover ring 303 can be provided and is disposed over the center gas injector 305.

The center gas injector 305 can be considered to provide a horizontal concentric gas inlet with multiple zones for injecting the reactant (process) gases into the reaction chamber 110 with planetary rotation of the satellites to compensate for precursor depletion.

In some embodiments, the center gas injector 305 can be temperature controlled via the coolant system and can be connected to gas sources for independently introducing one or more of a first reactant gas, second reactant gas, and/or inert gases into the reaction chamber 110. Further, the center gas injector 305 can comprise multiple injection zones stacked vertically. For example, in one embodiment, the center gas injector 305 can include a plurality of inlets for injection of the respective first reactant gas, second reactant gas, and inert gases into the reaction chamber 110. In one embodiment, the center gas injector 305 is a five-zone injector that provides good uniformity (thickness and doping) at high growth rates (50 μm/hr.). In the raised position, all zones (all of the inlets) are exposed and activated to allow unimpeded flow of the reactant gas from each of the inlets. Conversely, in the lowered position, none of the zones are activated and all of the inlets are closed off.

The susceptor base, shown as one segment 310 also includes a cover plate 330 and in accordance with the present disclosure, the cover plate 330 is removable which provides a number of advantages as discussed herein. The cover plate 330 has a first (top) surface and a second (bottom) surface. The second surface of the cover plate 330 is designed to complement and engage the first surface of the susceptor base 310 in that, in use, the cover plate 330 is disposed over and supported by the susceptor base 310. As shown, the cover plate 330 can have a slightly smaller footprint than the underlying susceptor base 310. The cover plate 330 has an opening 335 formed therein. The shape and size of the opening 335 is complementary to the shape and size of the raised center susceptor region 312 since the raised center susceptor region 312 axially aligns with and is exposed within the opening 335.

In accordance with the present disclosure, the cover plate 330 includes a set of recessed second tracks 340 that take the form of a pair of recessed channels that are parallel to one another. The set of second tracks 340 are linear tracks that are formed on either side of the opening 335. As illustrated, the set of second tracks 340 do not extend along the entire length of the opening 335 but instead only partially extend. In one embodiment, the set of second tracks 340 extend at least half of the length of the opening 335. The second tracks 340 are thus open along the first surface of the cover plate 330.

The cover plate 330 has a first end 331 that faces the center gas injector 305 and an opposite second end 333. The first end 331 can be located adjacent to the front cover plate 117 which is a separate structure relative to the cover 330. The second tracks 340 are open along the second end 333 but not the first end 331 since they do not extend all the way to the first end 331.

The recessed nature of the second tracks 340 along the first surface creates a pair of protruding rails 339 along the second surface of the cover plate 330. As illustrated, the recessed second tracks 340 can have a rectilinear shape and therefore, the protruding rails 339 have a rectilinear shape (i.e., the protruding rails 339 have inverse shape as the recessed second tracks 340). The bottom protruding rails 339 are configured to be received within the first tracks 310 and more particularly, the protruding rails 339 seat on the ledges 321 associated with the first tracks 310. Upstanding sidewalls that are along the sides ledges 321 serve to guide and hold the protruding rails 339 in place. In this manner, the cover plate 330 is coupled to the susceptor base 310.

It will be appreciated that since the protruding rails 339 sit on ledges 321, they do not enter into the rectilinear shaped recessed channel of the first tracks 320 and thus do not create interference within the recessed channels of the first tracks 320. The cover plate 330 thus closes off and covers the open first tracks 320. The second tracks 340 remain open along the top surface of the cover plate 330.

Thus, the cover plate 330 and the susceptor base 310 fit and are arranged in a nested arrangement.

The susceptor segment 310 also includes a satellite (disc) 350 that is received within the opening 335 and, in the case of a gas foil rotation mechanism, is thus in fluid communication with the gas distribution channels formed in the raised center susceptor region 312 to allow for the driving of the satellite 350. As understood, the satellite 350 is driven and provides a support of the carrier ring 360 on which the wafer 10 rests. FIG. 5 also shows axle 259 about which the disc 350 rotates.

A satellite (carrier) ring 360 surrounds the satellite 350 and is operatively coupled thereto such that rotation of the satellite 350 is imparted into rotation of the satellite ring 360 and wafer 10. The satellite ring 360 thus has an annular shape.

The satellite ring 360 can at least partially cover the inner ends of the second tracks 340 in that outer edges of the satellite ring 360 extend across inner ends of the second tracks 340. The satellite ring 360 has an upper face, a lower face, and inner and outer sidewalls. The inner sidewall includes a wafer shoulder 361 constructed and arranged to receive the wafer 10 thereon.

Much like the single wafer design, the two different sets of recessed tracks permit for independent removal of: (1) the wafer carrier (satellite ring 360 and wafer 10) and (2) removal of the cover plate 330 together with the disk 350. More specifically, the second tracks 340 permit for insertion of a tool (described below) that is disposed below and directly underneath outer portions of the satellite ring 360 that support the wafer 10. To remove the wafer, the satellite ring 360 is lifted by a wafer carrier transporter using a (robotic) tool that is inserted into second tracks 340 and then moved upward to cause a lifting of the satellite ring 360 and the wafer 10 off of the cover plate 330.

In contrast to conventional reactor design, the cover plate 330 itself is removable from the reaction chamber 110 to allow for improved and more efficient maintenance of the system 101. In other words, by permitting the cover plate 330 to be lifted and removed and a replacement cover plate 330 to be inserted, there is very little downtime associated with maintenance. In conventional design, the cover plate 330 is not removable and the system 101 needs to be shut down (no wafer processing) for a period of time to allows for adequate cleaning of the internal components, including the cover plate 330.

To remove the cover plate 330, the cover plate 330 is lifted by a transporter using a (robotic) tool that is inserted into first tracks 320 and then moved upward to cause a lifting of the cover plate 330. It will be appreciated that the cover plate 330 is lifted together with the disk 350 and removed after the satellite ring 360 and the wafer 10 have been removed.

FIG. 5 illustrates a center gas injector 305 such as one of the ones described and illustrated in U.S. patent application Ser. No. 63/428,250, filed Nov. 28, 2022, which is hereby incorporated by reference in its entirety.

In addition, in the segmented design of FIG. 5, the ceiling 109 is also segmented. However, it will be appreciated that segmenting of the ceiling is optional since the ceiling is not removed by the robotic tool.

### Automated Loading and Unloading of Single Wafer Carrier

As mentioned above, a robotic tool is used to automatically load and unload the single wafer carrier of FIG. 3 and each planetary wafer carrier of FIG. 5. In FIGS. 3 and 5, the robotic tool comprises an end effector 400 that is configured to load and unload the wafer carrier.

As is known, an end effector is the device at the end of a robotic arm that is configured to interact with the particular environment in which the robot is present. In the present environment, the end effector is a device that is engineered for handling wafers, for transferring them from one location to another.

Now referring to FIGS. 1 and 3, the end effector 400 is contained within a transport chamber 401 and is operatively coupled to a robotic device, such as a robot arm 409, that allows for controlled movement of the wafer carrier. The end effector 400 includes a pair of end effector fork arms 402. The fork arms 402 are parallel to one another and are spaced a prescribed distance such that the fork arms 402 can be inserted into the second tracks 240. The fork arms 402 are thus advanced linearly into the second tracks 240. As the fork arms 402 enter the second tracks 240, the fork arms 402 are advanced until a length of the fork arms 402 lies underneath outer portions of the carrier ring 260. Once the end effector 400 is in its fully extend position, the robotic arm 409 then lifts the end effector 400 and the fork arms 402 thereof resulting in lifting of the carrier ring 260 and thus lifting of the wafer 10. Once lifted, the robotic arm 409 is then retracted and then moved to cause the carrier ring 260 and wafer 10 to be removed from the reaction chamber 110. Additional drive mechanisms can be provided, such as a vacuum robot 399 (FIG. 1), can be provided for controlling movement of the end effector 400.

FIG. 1 illustrates that the transport chamber 401 is located adjacent to the reaction chamber 110 with an opening or port 405 being located between and providing selective communication between the transport chamber 401 and the reaction chamber 110. A first gate valve 407 can be provided to seal the two chambers from one another or open them up to each other.

FIG. 1 also illustrates a storage chamber 50 that is in selective communication with the transport chamber 401. An opening or port 52 being located between and providing selective communication between the transport chamber 401 and the storage chamber 50. A second gate valve 55 can be provided to seal the two chambers from one another or open them up to each other. Within the storage chamber 50 there is a storage shelf 53 that can hold an object such as the wafer carrier with wafer. A lift motor 59 is operatively coupled to the storage shelf 53 for raising and lowering the storage shelf 53. A door 57 is provided as part of the storage chamber 50 for providing access to the inside of the storage chamber 50.

The loading/unloading process can include the following steps: moving the carrier out of the reactor; placing the carrier into a wafer loading and unloading station; separating the wafer 10 from the carrier ring 260; moving the carrier ring 260 to storage; moving the cleaned carrier (with cleaned carrier ring 260) to the wafer loading and unloading station; loading a fresh wafer 10 onto the carrier ring 260; moving the fresh carrier with wafer 10 into the position in the reactor.

FIGS. 6A-6E are cross-sectional views illustrating steps for transferring the wafer 10 and performing preventative maintenance on the cover plate 230. For purpose of illustration only, FIGS. 6A-6E illustrate the single wafer system 101 of FIG. 3; however, it will be appreciated that, as described herein, the automated wafer transfer mechanism/steps shown in FIGS. 6A-6E are equally applicable to the planetary wafer design shown in FIG. 5.

FIG. 6A shows the two different positions of the end effector 400 in that, as described above, in an upper position, the end effector 400 is inserted into the second tracks 240 for wafer carrier transfer and in the lower position, the end effector 400 is inserted into the first tracks 220 for cover plate transfer.

FIG. 6B illustrates an end effector transfer position of the carrier in which the carrier ring 260 and the wafer 10 are supported by the fork arms 402 of the end effector 400 and is shown raised relative to the disc 250 and the cover plate 230. More specifically, in FIG. 6B, the fork arms 402 are inserted into the second tracks 240 defined by and along the top surface of the cover plate 230. Once in this position, the fork arms 402 are underneath the carrier ring 260.

FIG. 6C shows a raised position in which after insertion of the fork arms 402 within the second tracks 240, the fork arms 402 are raised. As the fork arms 402 are raised, the carrier ring 260 is likewise raised along with the wafer 10 that is supported by the carrier ring 260. The end effector 400 then moves (by robotics) to a target position such as a position at which the wafer 10 can be unloaded and/or processed. Once the carrier ring 260 is lifted, the second tracks 240 become open along the tops thereof.

FIG. 6D shows the fork arms 402 inserted into the first tracks 220 beneath the removable cover plate 230. The step in FIG. 6D is performed subsequent to the step in FIG. 6C and therefore, the carrier ring 260 and the wafer 10 have been removed. In this position, the fork arms 402 are positioned to support the underside of the cover plate 230.

FIG. 6E shows a raised position in which after insertion of the fork arms 402 within the first tracks 220, the fork arms 402 are raised. As the fork arms 402 are raised, the cover plate 230 is likewise raised together with the disc 250. The end effector 400 then moves (by robotics) to a target position such as a position at which the cover plate 230 and the disc 250 can be unloaded and/or processed (e.g., cleaned).

In conventional reactor design, the cover plate is not removable and is a fixed part of the reactor chamber and requires much more elaborate and time consuming cleaning processes. In contrast, in the reactors disclosed herein, the cover plate 230 is fully removable. When it comes to cleaning and/or replacement of the cover plate 230, as mentioned, the end effector 400 is used to lift up the cover plate 230 up and then remove it from the reaction chamber 110.

With respect to the planetary wafer design of FIG. 5, that is made up of the plurality of susceptor segments 310, the loading/unloading process can include the following steps: moving one susceptor satellite ring 360 with wafer 10 out of the reactor and placing them into a wafer loading and unloading station; separating the wafer 10 from satellite ring 360; moving the satellite ring 360 to storage; removing the cover plate 330 with satellite disc 350 for cleaning and bringing into the reaction chamber a cleaned susceptor cover plate 330 and satellite disc 350); loading a satellite ring 360 onto the cleaned newly replaced susceptor satellite disc 350 and cover plate 330; rotating the susceptor segment 310 to the unloading position in the reactor and repeating the same sequences until the reactor is filled with fresh susceptor cover plates 330 and satellite discs 350 and wafers 10 on satellite rings 360. There are two possible designs for the planetary reactor. For RF heating, the susceptor is one large torus and in this case only the cover plate is removed. For resistive heating, the susceptor can be segmented and in this case the susceptor inclusive of cover plate can be removed. Cleaning of the susceptor is likely necessary for deposition of III-N materials.

When it comes to cleaning of the cover plate 330 of each susceptor segment 310, as mentioned, the end effector 400 is used to lift the cover plate 330 up and then remove it from the reaction chamber 110. To remove all of the cover plates 330, the susceptor segments 310 are rotated to allow for successive removal of the cover plates 330.

It will be appreciated that the end effector 400 used in the planetary wafer design is identical or similar to the one used in the single wafer design (FIG. 3) with the exception that the spacing between the fork arms will be smaller in the end effector 400 for the planetary wafer design since the end effector is only lifting one susceptor segment 400 at a time versus the entire susceptor as in the case of the single wafer design.

When it comes to cleaning and/or replacement of the cover plate 230, as mentioned, the end effector 400 is used to lift up the cover plate 430 from one susceptor segment 310 and then remove it from the reaction chamber 110. This process is repeated for each cover plate 430 that is intended to be removed from the reaction chamber 110.

It will be understood that, in accordance with the present disclosure, the floor of the reactor that comprises the wafer 10, wafer support (carrier) ring 260, 360, satellite disc 250, 350, and the carrier (cover plate 230, 330) is mostly removable by the automated handling system. The wafer 10 and wafer support ring 260, 360 are removed and exchanged after each run while the remaining components (including the cover plate 230, 330) together with the disc 250, 350 are exchanged every 10+ runs when the parasitic deposition on these surfaces begins to shed particles or affects the doping level. The carrier may be circular, rectangular, or oval for compatibility with the automated handling system. A circular carrier is illustrated. The frequency of removal of the cover or cover along with a segmented carrier depends on the type of material being grown. For III-N materials, more frequent exchange is expected than for SiC.

An alternative approach to limiting the buildup on portions of the floor that cannot be removed by the automated handling system is active cooling to maintain a surface temperature of 900° C.-1100° C. Within this temperature range, the parasitic deposition on these surfaces is reduced to an acceptable deposition rate. A water-cooled plate that is placed in proximity to the hot surfaces can provide active cooling.

In many applications, the wafers must be loaded and unloaded from the reactor at ≤900° C. to avoid damage to the wafer compared to the process temperature of −1650° C. Thus, the reactor must cycle between 900° C. and 1650° C. Fast heat-up and cool-down are desirable to minimize the cycle time. While the heat-up rate can be increased by increasing the heater power and decreasing the thermal mass of the reactor cell, the cool-down rate is limited by the insulation that surrounds the reactor cell. Gas cooling channels may be embedded within the walls of the reactor cell. Chilled gas can be introduced through these gas cooling channels after the process has been completed to enhance the cool-down rate. The gas can be chilled prior to introduction into the reactor walls by adiabatic expansion of high-pressure gas. The cooling gas can be exhausted into the water-cooled chamber within which the reactor cell is placed.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

What is claimed is:

1. A chemical vapor deposition system comprising:
a reaction chamber;
a removable wafer carrier including a wafer carrier body that is configured to support a wafer;
a removable cover plate that is placed below the disk;
a susceptor base disposed below the cover plate that supports the cover plate; and
a common end effector that is configured to independently remove the removable wafer carrier and the removable cover plate from the reaction chamber.

2. A chemical vapor deposition system comprising:
a reaction chamber;
a removable wafer carrier including a wafer carrier body that is configured to support a wafer;
a removable cover plate that is placed below the disk;
a susceptor base disposed below the cover plate that supports the cover plate; and
multiple independently controlled heaters that surround the reaction chamber to control temperature and temperature distribution on select heater surfaces within the reaction chamber.

3. A chemical vapor deposition system comprising:
a reaction chamber;
a removable wafer carrier including a wafer carrier body that is configured to support a wafer;
a removable cover plate that is placed below the disk;
a susceptor base disposed below the cover plate that supports the cover plate;
a pair of first end effector tracks formed within and along a top surface of the susceptor base for receiving a pair of fork arms of an end effector for lifting the cover plate and the disk away from the susceptor base to allow removal and maintenance of the removable cover plate and the disk; and
a pair of second end effector tracks formed within and along a top surface of the cover plate for receiving the pair of fork arms of the end effector for lifting the wafer carrier to allow removal thereof.

4. The chemical vapor deposition system of claim 3, wherein the reaction chamber includes:
an exhaust system;
a ceiling;
a gas injector;
a ceiling heater assembly disposed along the ceiling above the wafer carrier for heating the ceiling of the reaction chamber; and
a susceptor heater assembly positioned beneath the wafer carrier.

5. The chemical vapor deposition system of claim 3, wherein the gas injector comprises a ceiling injector positioned along the ceiling over the wafer carrier for injecting gas into the reaction chamber and at least one of a lateral gas injector and a movable center gas injector positioned in a center of the wafer carrier that comprises a multi-wafer carrier.

6. The chemical vapor deposition system of claim 5, wherein the ceiling injector comprises a showerhead ceiling injector positioned along the ceiling over the wafer carrier for injecting gas into the reaction chamber, the showerhead ceiling injector including a top ceiling plate and a lower ceiling plate spaced from the top ceiling plate with an open gas distribution space formed therein, the lower ceiling plate having showerhead holes formed therethrough for injecting the gas into the reaction chamber.

7. The chemical vapor deposition system of claim 3, wherein the reaction chamber includes heated sidewalls.

8. The chemical vapor deposition system of claim 3, wherein the wafer carrier comprises a multi-wafer carrier including a wafer carrier body and a plurality of wafer carrier discs supported within the wafer carrier body.

9. The chemical vapor deposition system of claim 3, further including:
a gas driven drive mechanism for rotating the wafer carrier, the wafer carrier having gas distribution channels with a flow direction that is directed circumferentially so that it imposes a rotary momentum on the wafer carrier.

10. The chemical vapor deposition system of claim 3, wherein the wafer carrier comprises a rotatable disc that is supported by the removable cover plate and is removable therewith.

11. The chemical vapor deposition system of claim 3, wherein the pair of first end effector tracks are recessed along a top surface of the susceptor base with a recessed ledge being formed on either side of each first end effector track, each recessed ledge being configured to receive a corresponding protruding portion of the cover plate for securely coupling the cover plate to the susceptor base.

12. The chemical vapor deposition system of claim 11, wherein each first end effector track has a rectilinear shape and the recessed ledge comprises a flat linear surface on each side and at a top of the first end effector track.

13. The chemical vapor deposition system of claim 12, wherein the pair of first end effector tracks extend partially along a raised platform of the susceptor base which is axially aligned with an opening of the cover plate.

14. The chemical vapor deposition system of claim 13, wherein the raised platform comprises a gas foil rotation drive mechanism.

15. The chemical vapor deposition system of claim 13, wherein the pair of first end effector tracks extend at least along ½ of a length of the raised platform.

16. The chemical vapor deposition system of claim 3, wherein the pair of first end effector tracks are open along a first end of the susceptor base but terminate prior to reaching an opposite second end of the susceptor base.

17. The chemical vapor deposition system of claim 3, wherein the pair of second end effector tracks are recessed along the top surface of the cover plate and define a pair of protruding rails along a bottom surface of the cover plate, each protruding rail being received within and seating against a respective recessed ledge formed in the susceptor base on each side of one respective first end effector track.

18. The chemical vapor deposition system of claim 17, wherein the pair of protruding rails cover but do not enter into the pair of first end effector tracks and receipt of the pair of protruding rails into the recessed ledges prevents unintended lateral movement of the cover plate relative to the susceptor base.

19. The chemical vapor deposition system of claim 3, wherein the cover plate includes an opening and the pair of second end effector tracks extend partially along the opening of the cover plate.

20. The chemical vapor deposition system of claim 19, wherein the pair of second end effector tracks extend at least along ½ of a length of the opening.

21. The chemical vapor deposition system of claim 3, wherein the wafer carrier includes a carrier ring including an inner edge for receiving an outer perimeter edge of the wafer, wherein carrier ring is configured to seat within the cover plate and a length of each of the pair of the second end effector tracks is located directly beneath the carrier ring to facilitate raising and lowering thereof relative to the cover plate.

22. A chemical vapor deposition system comprising:
a reaction chamber;
a removable wafer carrier including a wafer carrier body that is configured to support a wafer;
a removable cover plate; and
a susceptor base disposed below the cover plate that supports the cover plate;
wherein the removable cover plate is in a nested arrangement with respect to the susceptor base as a result of first nesting structure of the removable cover plate mating with a second nesting structure of the susceptor base.

23. A multi-wafer chemical vapor deposition system comprising
a reaction chamber;
a removable segmented multi-wafer carrier comprising a plurality of wafer carrier segments, each wafer carrier segment including:
a wafer carrier disc supported within the wafer carrier segment;
a wafer carrier body segment for supporting a wafer;
a removable cover plate segment that supports the wafer carrier body segment;
a susceptor base segment disposed below the cover plate segment that supports the cover plate segment;
a pair of first end effector tracks formed within and along a top surface of the susceptor base segment for receiving a pair of fork arms of an end effector for lifting the cover plate segment away from the susceptor base segment to allow removal and maintenance of the removable cover plate segment; and
a pair of second end effector tracks formed within and along a top surface of the cover plate segment for receiving the pair of fork arms of the end effector for lifting the wafer carrier body to allow removal thereof.

24. The multi-wafer chemical vapor deposition system of claim 23, further including a movable center gas injector positioned in a center of the segmented multi-wafer carrier, the center gas injector comprising a reactant gas inlet port with a plurality of injection zones, the center gas injector moving between a raised position in which the plurality of injection zones are in fluid communication with the reaction chamber and a lowered position in which the plurality of injection zones are closed off from the reaction chamber.

25. The multi-wafer chemical vapor deposition system of claim 23, wherein the system comprises a multi-wafer metal organic chemical vapor deposition system.

26. The multi-wafer chemical vapor deposition system of claim 23, wherein the reaction chamber is defined by sidewalls and the system further includes a sidewall heater for actively heating the sidewalls to approximately 1800° C.

27. The chemical vapor deposition system of claim 23, wherein the reaction chamber includes:
an exhaust system;
a ceiling;
a gas injector;
a ceiling heater assembly disposed along the ceiling above the multi-wafer carrier for heating the ceiling of the reaction chamber; and
a susceptor heater assembly positioned beneath the multi-wafer carrier.

28. The chemical vapor deposition system of claim 5, wherein the reaction chamber includes:
an exhaust system;
a ceiling;
a gas injector;
a ceiling heater assembly disposed along the ceiling above the multi-wafer carrier for heating the ceiling of the reaction chamber; and
a susceptor heater assembly positioned beneath the multi-wafer carrier.

29. The chemical vapor deposition system of claim 27, wherein the gas injector comprises a showerhead ceiling injector positioned along the ceiling over the multi-wafer carrier for injecting gas into the reaction chamber, the showerhead ceiling injector including a top ceiling plate and a lower ceiling plate spaced from the top ceiling plate with an open gas distribution space formed therein, the lower ceiling plate having showerhead holes formed therethrough for injecting the gas into the reaction chamber.

30. The chemical vapor deposition system of claim 27, wherein the injected gas comprises a reactive gas injected through the showerhead holes to suppress deposition on the ceiling.

31. A method for performing preventative maintenance of a chemical vapor deposition system that includes a reaction chamber, the method comprising the steps of:
inserting an end effector into a pair of second end effector tracks defined along a top surface of a removable cover plate;
lifting a removable wafer carrier by raising the end effector, the wafer carrier including a wafer carrier body that is configured to support a wafer;
inserting the end effector into a pair of first end effector tracks defined along a top surface of a susceptor base, the first end effector tracks being closed off by an underside of the cover plate;
lifting the removable cover plate by raising the end effector; and
removing the removable cover plate from the reaction chamber and replacing the removable cover plate with a clean cover plate using the end effector.
